(19) United States
(12) Patent Application Publication
(10) Pub. No.: US 2011/0157815 A1
(43) Pub. Date: Jun. 30, 2011

(54) SERVER STRUCTURE WITH A REPLACEABLE HEAT-DISSIPATING MODULE

(75) Inventor: Tse Min LIN, Sijhih City (TW)

(73) Assignee: LANNER ELECTRONIC INC., Sijhih City (TW)

(21) Appl. No.: 12/649,280

(22) Filed: Dec. 29, 2009

(51) Int. Cl. G06F 1/20; H05K 7/20

(52) U.S. Cl. 361/679.48; 361/679.46

(57) ABSTRACT

A server structure with a replaceable heat-dissipating module comprises at least one heat-dissipating module receiving slot and at least one heat-dissipating module. The heat-dissipating module receiving slot is provided in a case and has two lateral walls each provided with a sliding groove. The heat-dissipating module further comprises a heat-dissipating element and two side boards. The two side boards are located at two sides of the heat-dissipating element for engaging with the sliding grooves, respectively, so that the heat-dissipating module receiving slot replaceably receives the heat-dissipating module therein.

### BACKGROUND OF THE INVENTION

1. Technical Field

The present invention relates to a server structure and more particularly, to a server structure with a replaceable heat-dissipating module.

2. Description of Related Art

In recent years, due to the progress of information technology and the popularization of computer network use, various applications about servers have been increasingly developed. Principally, a server is a core computer in a network system for serving other computers in the system. It provides functions of web-drive or web-printer desired by network users, while allowing user terminals to share resources in the network environment.

A conventional server is composed of a motherboard, a CPU and at least one hard drive, with or without other electronic devices, which are all fixed in an accommodating space inside a housing by means of screws. A cover plate is used to close an opening of the housing, for preventing dust and foreign matters invading and damaging the electronic devices.

Therein, the electronic devices can generate considerable heat during operation. Since the space storing the electronic devices has been closed by the cover plate, the heat has no way to spread out and move away from the housing. When the temperature in the server keeps going up, it is likely that the electronic devices therein get damaged. For solving this problem, at least one heat-dissipating element is typically set in the housing for removing the heat and remaining the server cool.

However, in the conventional server structure, the heat-dissipating element is also fixed inside the housing of the server by means of screws. When there is a need to disassemble the heat-dissipating element from the housing due to malfunction of the heat-dissipating element or other reasons, it is necessary to first remove the cover plate of the server from the housing, and then to unscrew the screws fixing the heat-dissipating element, thereby allowing the heat-dissipating element to be detached. For reattaching a new heat-dissipating element into the housing, the above series of actions has to be performed in a reverse order. Therefore, the conventional server structure is disadvantageous because processes for attaching and detaching the heat-dissipating element are time consuming, labor requiring and jeopardizing other electronic devices if careless operation happens in repeated assembly and disassembly.

Thus, there is a need for an improved server structure with a heat-dissipating element that is easy to be attached and detached while the firmness of the assembled server structure is also ensured.

### BRIEF SUMMARY OF THE INVENTION

In view of the defects of the prior art, the inventor of the present invention implemented his years of experience, imagination and creativity, after numerous tests and modifications, and has eventually developed a server structure with a replaceable heat-dissipating module.

The primary objective of the present invention is to provide a server structure with a replaceable heat-dissipating module, wherein the heat-dissipating module is easy to be attached and detached.

Another objective of the present invention is to provide a server structure with a replaceable heat-dissipating module, wherein the server structure achieves good power connection.

Still another objective of the present invention is to provide a server structure with a replaceable heat-dissipating module, wherein the heat-dissipating module is configured to be firmly positioned in the server.

Hence, the present invention herein discloses a server structure with a replaceable heat-dissipating module, the server structure at least including:

a housing for receiving various electronic devices, the housing having an interior divided into a main element accommodating space and at least one heat-dissipating module receiving slot, the heat-dissipating module receiving slot at least defined by: two lateral walls, each having a surface provided with a lengthwise extending sliding groove; a retaining wall, settled between the two lateral walls for separating the heat-dissipating module receiving slot from the main element accommodating space, the retaining wall further having a plurality of vents for ventilation;

a power connection port, settled on the retaining wall, the power connection port at an end facing the heat-dissipating element provided with a plurality of connection terminals;

at least one heat-dissipating module, being replaceably received in the heat-dissipating module receiving slot, the heat-dissipating module serving to dissipate heat generated by electronic devices in the housing for remaining the server structure cool, the heat-dissipating module including: a heat-dissipating element, enabling the heat-dissipating module to perform heat dissipation; two side boards, provided at two sides of the heat-dissipating element, the two side boards being configured to fittingly couple with the sliding grooves on the two lateral walls of the heat-dissipating module receiving slot, so that the heat-dissipating module replaceably positioned and well supported; and a power connection unit, settled at an end of the heat-dissipating element facing the main element accommodating space, the power connection unit being configured to connect with the plurality of connection terminals on the power connection port for powering the heat-dissipating element.

### BRIEF DESCRIPTION OF THE SEVERAL VIEWS OF THE DRAWINGS

The invention as well as a preferred mode of use and advantages thereof will be best understood by referring to the following detailed description of the illustrative embodiments in conjunction with the accompanying drawings, wherein:

FIG. 1 is a schematic perspective view of the inner structure of the server according to a first preferred embodiment of the present invention;

FIG. 2 is a schematic perspective view of a partially engaged heat-dissipating module and a heat-dissipating module receiving slot according to the first preferred embodiment of the present invention;

FIG. 3 is a schematic perspective view of the heat-dissipating module receiving slot according to the first preferred embodiment of the present invention;

FIG. 4 is a schematic perspective view of the heat-dissipating module according to the first preferred embodiment of the present invention;

FIG. 5 is a schematic perspective view of the inner structure of the server according to a second preferred embodiment of the present invention;

FIG. 6 is a schematic perspective view of a partially engaged heat-dissipating module and a heat-dissipating module receiving slot according to the second preferred embodiment of the present invention;

FIG. 7 is a schematic perspective view of the heat-dissipating module receiving slot according to the second preferred embodiment of the present invention;

FIG. 8A is a schematic perspective view of the heat-dissipating module according to the second preferred embodiment of the present invention; and

FIG. 8B is another schematic perspective view of the heat-dissipating module according to the second preferred embodiment of the present invention taken from a different visual angle.

### DETAILED DESCRIPTION OF THE INVENTION

For achieving the foregoing objectives and effects, the inventor implemented modulized design to heat-dissipating elements and made structural improvement to the server housing. After numerous corrections and adjustments, a server structure with a replaceable heat-dissipating module of the present invention is now provided. Hereinafter, a first preferred embodiment and a second preferred embodiment will be described in detail for illustrating a server structure with a replaceable heat-dissipating module of the present invention.

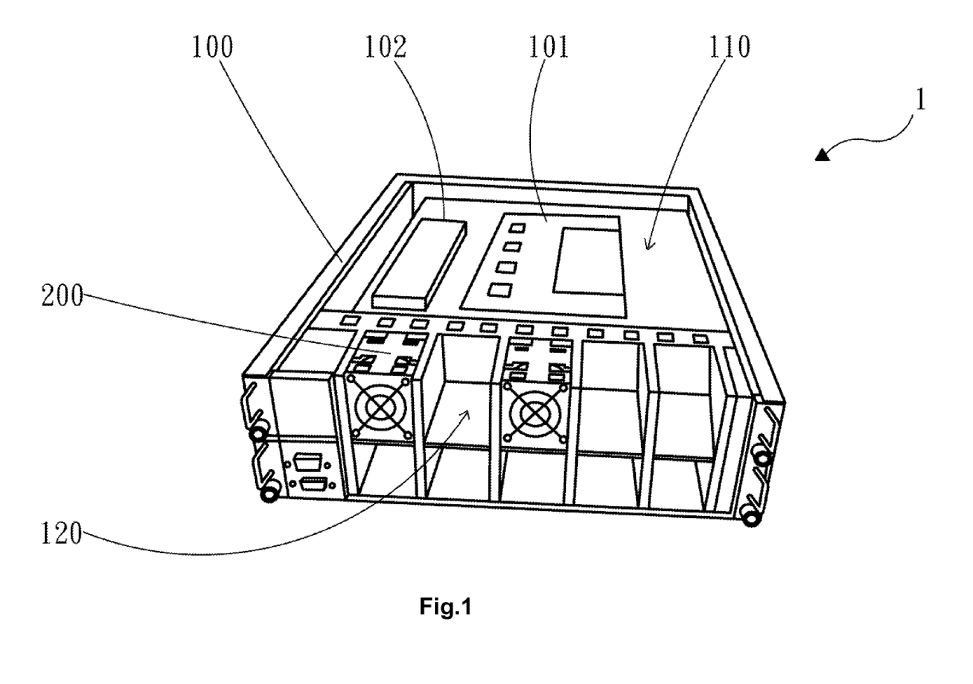

Referring to FIG. 1, there is a schematic perspective view of an inner structure of a server 1 according to the first preferred embodiment of the present invention. The server 1 comprises a housing 100 and a plurality of heat-dissipating modules 200. The interior of the housing 100 is divided into a main element accommodating space 110 and a plurality of heat-dissipating module receiving slots 120. The main element accommodating space 110 is configured to accommodate electronic devices required by the server 1, such as a motherboard 101 and a hard drive 102. The plurality of heat-dissipating modules 200 are replaceably received in the heat-dissipating module receiving slots 120, for dissipating heat generated by the electronic devices so as to remain the server 1 cool.

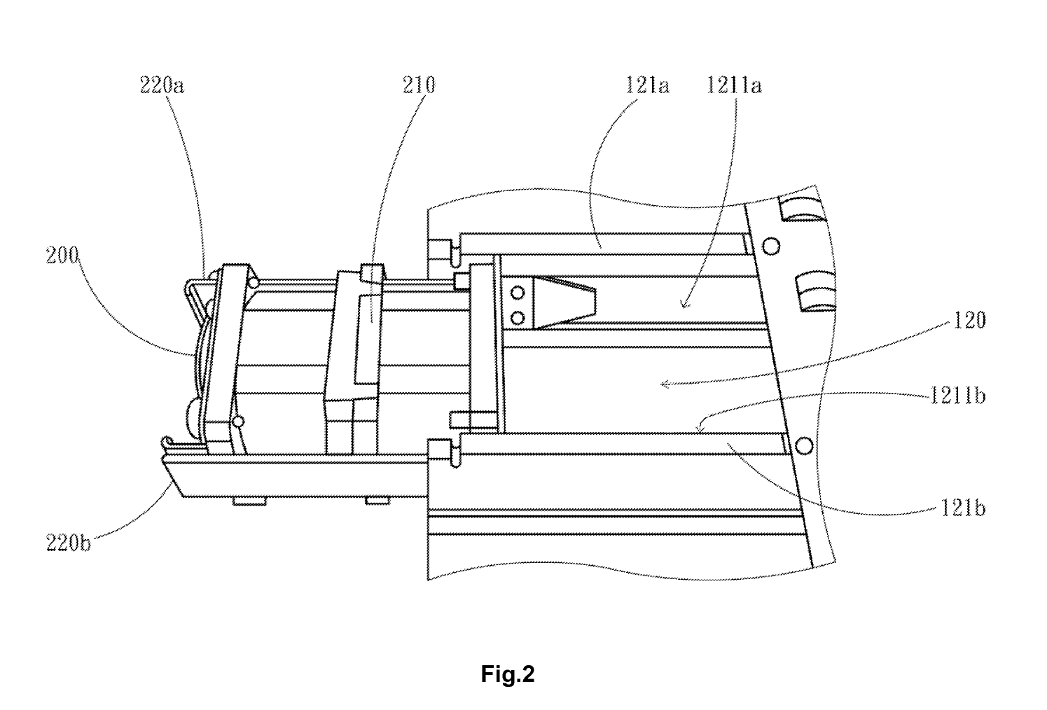

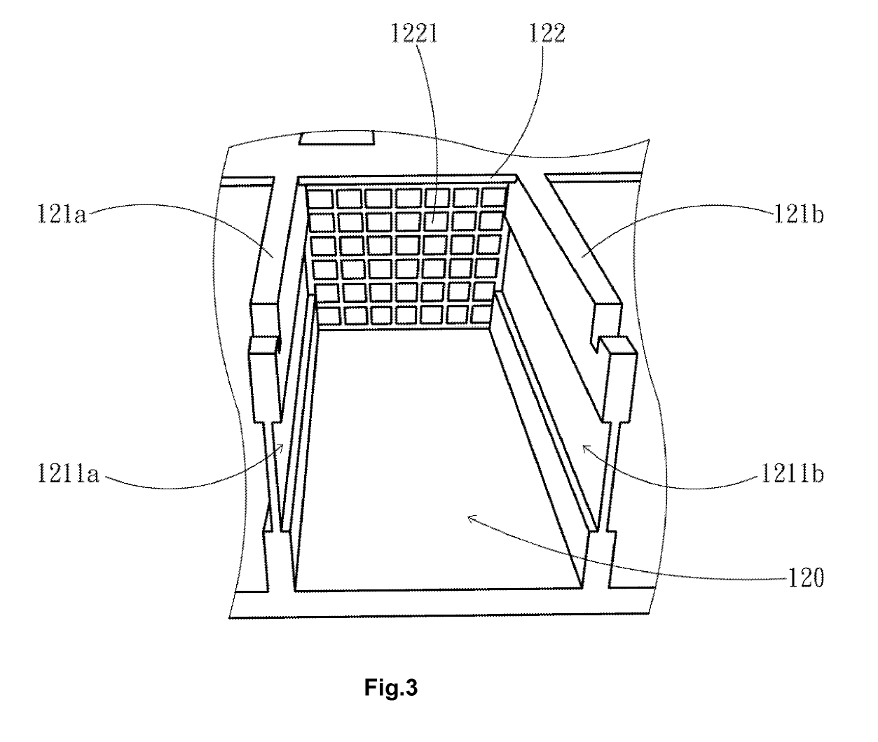

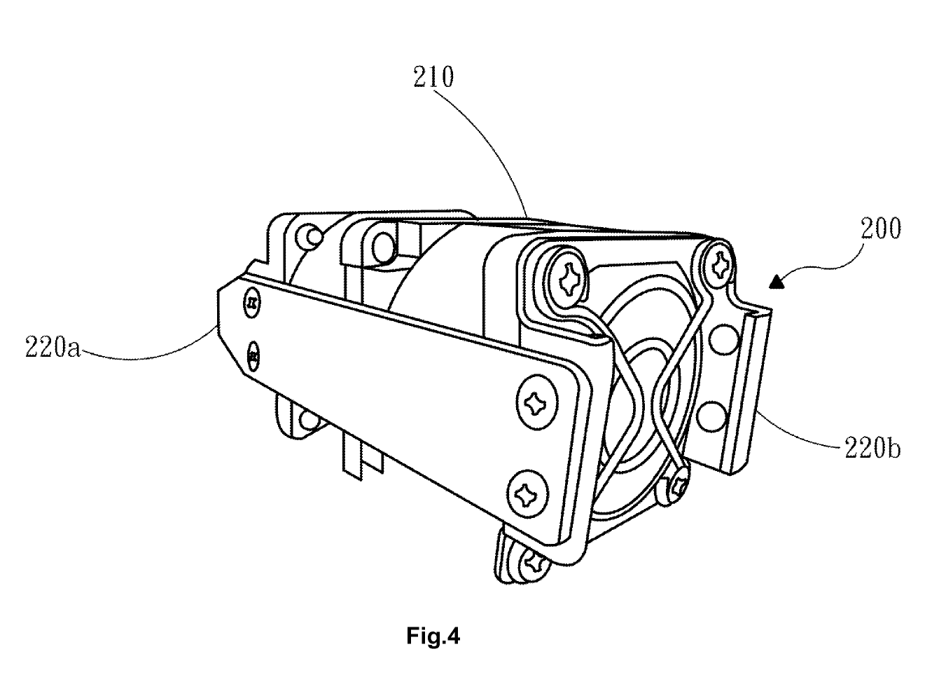

Please refer to FIG. 2, FIG. 3 and FIG. 4 together. FIG. 2 is a schematic perspective view of the partially engaged heat-dissipating module 200 and the heat-dissipating module receiving slot 120 according to the first preferred embodiment of the present invention. FIG. 3 is a schematic perspective view of the heat-dissipating module receiving slot 120 according to the first preferred embodiment of the present invention. FIG. 4 is a schematic perspective view of the heat-dissipating module 200 according to the first preferred embodiment of the present invention. As can be seen in the drawings, each of the heat-dissipating module receiving slots 120 is defined by two lateral walls 121a, 121b and a retaining wall 122. The two lateral walls 121a, 121b have their surfaces respectively provided with a sliding groove 1211a or 1211b, both extending from an edge adjacent to the retaining wall 122 toward an opposite edge of the lateral wall 121a or 121b. The retaining wall 122 has two edges thereof perpendicularly border on the two lateral walls 121a, 121b, for separating the heat-dissipating module receiving slot 120 from the main element accommodating space 110. The retaining wall 122 further has a plurality of vents 1221 for ventilation.

The heat-dissipating module 200 additionally has a heat-dissipating element 210 and two side boards 220a, 220b. The heat-dissipating element 210 is the major part in the heat-dissipating module 200 to perform the heat-dissipating function. It is a fan capable of heat dissipation in two ways. The first way is that the fan blows wind toward the main element accommodating space 110 so as to introduce cool air outside the housing 100 into the main element accommodating space 110. The second way is that the fan blows wind outward from the housing 100 so as to expel warm air in the main element accommodating space 110 from the housing 100, thereby remaining the server 1 cool. The two side boards 220a, 220b are provided at two sides of the heat-dissipating element 210 and are configured to fittingly couple with the sliding grooves 1211a, 1211b on the two lateral walls 121a, 121b of the corresponding heat-dissipating module receiving slot 120. Thereby, the heat-dissipating module 200 can be replaceably positioned and well supported.

Additionally, in the foregoing first preferred embodiment, though the heat-dissipating module 200 and the heat-dissipating module receiving slot 120 can be firmly combined in virtue of the engagement between the side boards 220a, 220b and the lateral walls 121a, 121b, for further improving the structural security, some assistive parts may be implemented. For example, a pair of matching buckle pieces may be settled on the heat-dissipating module 200 and the heat-dissipating module receiving slot 120 correspondingly so that when the heat-dissipating module 200 is attached to the heat-dissipating module receiving slot 120, the buckle pieces engage mutually, thereby fastening the heat-dissipating module 200 to the heat-dissipating module receiving slot 120. Alternatively, one magnetic member may be set at an end of the heat-dissipating module 200 facing the main element accommodating space 110 while another magnetic member is settled on the retaining wall 122 so that when the heat-dissipating module 200 is attached to the heat-dissipating module receiving slot 120, the two magnetic members perform magnetic attraction therebetween, thereby fastening the heat-dissipating module 200 to the heat-dissipating module receiving slot 120.

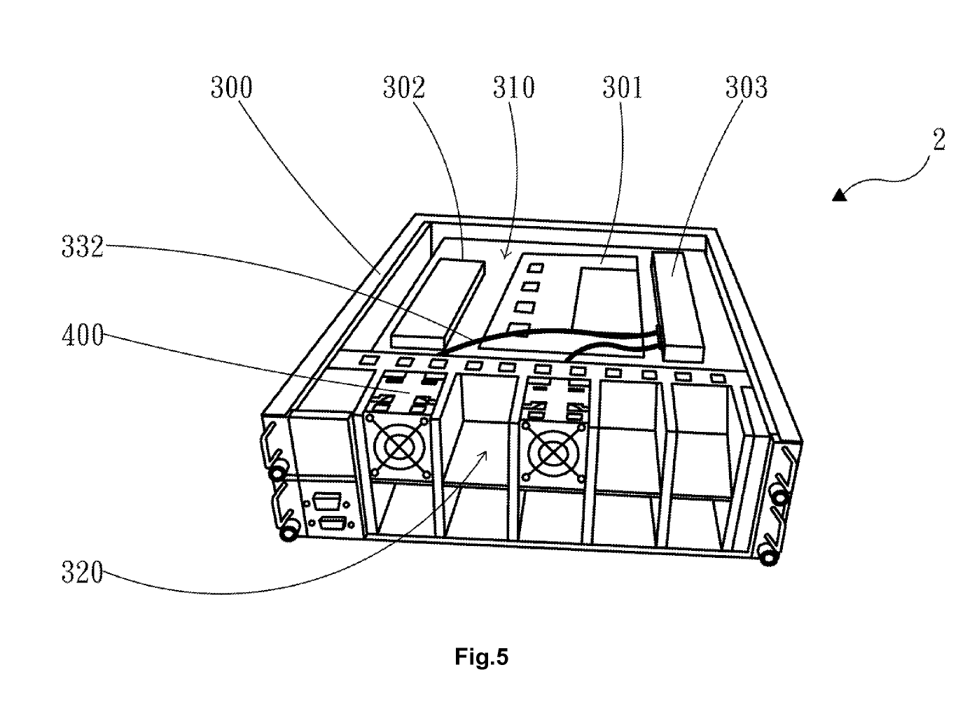

Then a server structure with a replaceable heat-dissipating module according to the second preferred embodiment of the present invention will be illustrated. FIG. 5 is a schematic perspective view of the inner structure of the server 2 according to the second preferred embodiment of the present invention. The server 2 comprises a housing 300 and a plurality of heat-dissipating modules 400. The interior of the housing 300 is divided into a main element accommodating space 310 and a plurality of heat-dissipating module receiving slots 320. The main element accommodating space 310 is configured to accommodate electronic devices required by the server 2, such as a motherboard 301, a hard drive 302 and a power supply 303. The plurality of heat-dissipating modules 400 are replaceably received in the heat-dissipating module receiving slots 320, for dissipating heat generated by the electronic devices so as to remain the server 2 cool.

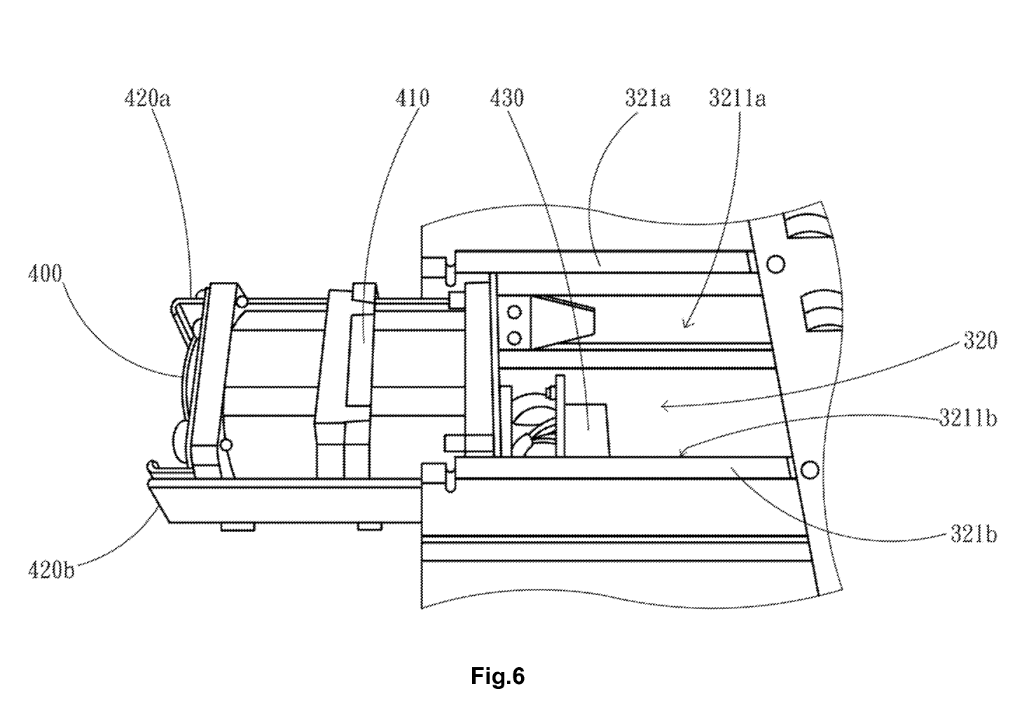

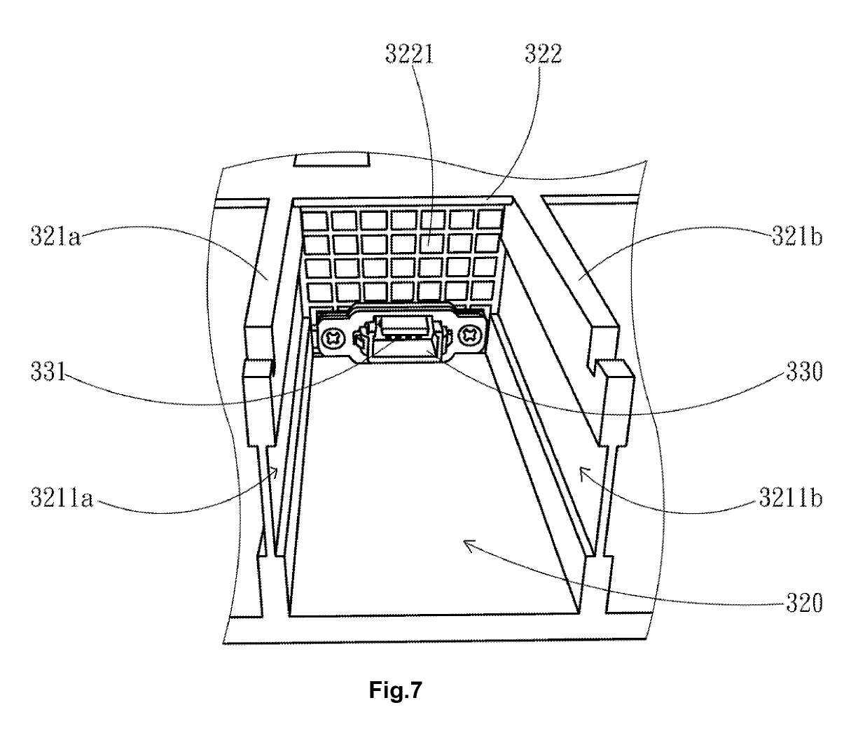

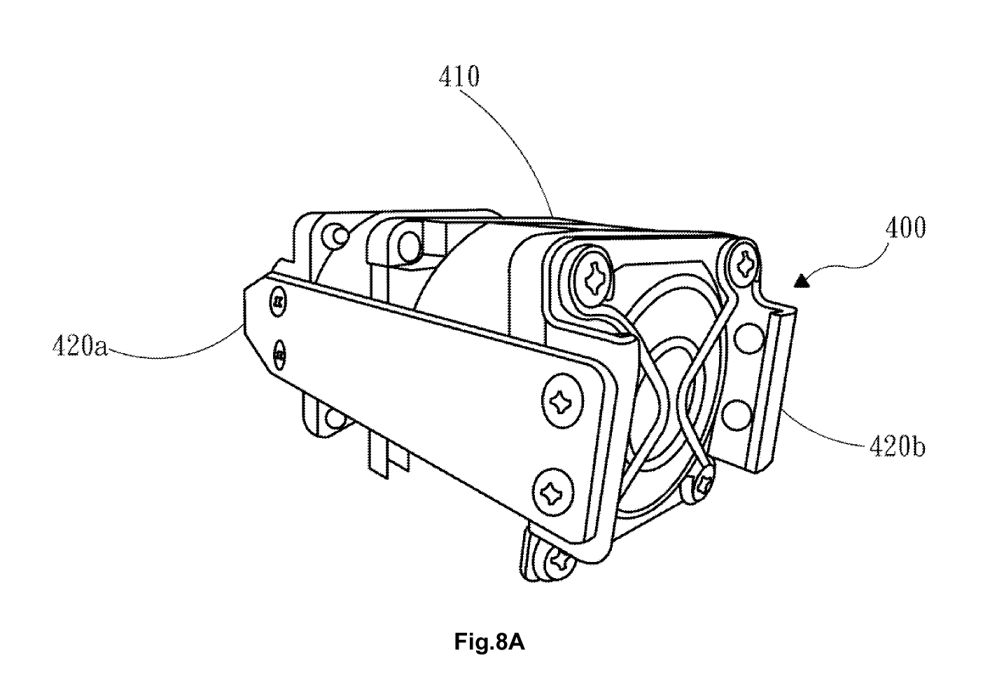

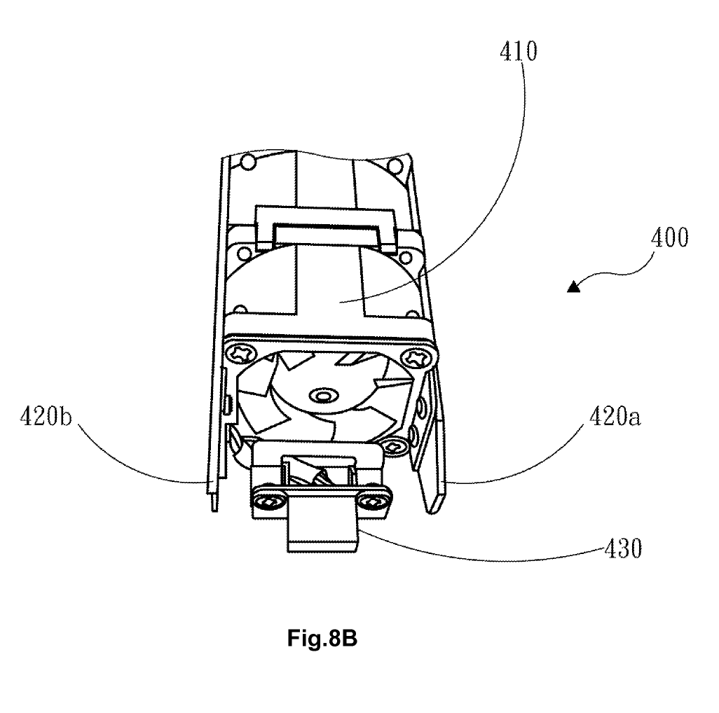

Please refer to FIG. 6, FIG. 7, FIG. 8A and FIG. 8B together. FIG. 6 is a schematic perspective view of the partially engaged heat-dissipating module 400 and the heat-dissipating module receiving slot 320 according to the second preferred embodiment of the present invention. FIG. 7 is a schematic perspective view of the heat-dissipating module receiving slot 320 according to the second preferred embodiment of the present invention. FIGS. 8A and 8B are schematic perspective views of the heat-dissipating module 400 according to the second preferred embodiment of the present invention taken from two visual angles. As can be seen in the drawings, the heat-dissipating module receiving slot 320 is defined by two lateral walls 321a, 321b and a retaining wall 322. The two lateral walls 321a, 321b have their surfaces respectively provided with a sliding groove 3211a or 3211b, both extending from an edge adjacent to the retaining wall 322 toward an opposite edge of the lateral wall 321a, 321b. The retaining wall 322 has two edges thereof perpendicularly border on the two lateral walls 321a, 321b, for separating the heat-dissipating module receiving slot 320 from the main element accommodating space 310. The retaining wall 322 further has a plurality of vents 3221 for ventilation. Moreover, the retaining wall 322 is further provided thereon with a power connection port 330. The power connection port 330 has a plurality of connection terminals 331 settled at an end thereof facing the interior of the heat-dissipating module receiving slot 320 and has a power connection cord 332 settled at an opposite end facing the main element accommodating space 310. The power connection port 330 is thereby connected with the power supply 303 through the power connection cord 332 (as shown in FIG. 5).

The heat-dissipating module 400 also comprises a heat-dissipating element 410, two side boards 420a, 420b and a power connection unit 430. The heat-dissipating element 410 is the major part in the heat-dissipating module 400 to perform the heat-dissipating function. It is a fan capable of heat dissipation in two ways. The first way is that the fan blows wind toward the main element accommodating space 310 so as to introduce cool air outside the housing 300 into the main element accommodating space 310. The second way is that the fan blows wind outward from the housing 300 so as to expel warm air in the main element accommodating space 310 from the housing 300, thereby remaining the server 2 cool. The two side boards 420a, 420b are provided at two sides of the heat-dissipating element 410 and are configured to fittingly couple with the sliding grooves 3211a, 3211b on the two lateral walls 321a, 321b of the corresponding heat-dissipating module receiving slot 320. Thereby, the heat-dissipating module 400 can be replaceably positioned and well supported. The power connection unit 430 is located at the end of the heat-dissipating element 410 facing the main element accommodating space 310 so that the power connection unit 430 can be connected with the plurality of connection terminals 331 on the power connection port 330, thereby powering the heat-dissipating elements 410.

In the second preferred embodiment, the assistive means for reinforcing combination between the heat-dissipating module 400 and the heat-dissipating module receiving slot 320 are similar to those described in the first preferred embodiment and need not to be discussed here in detail.

Through the above detailed description to the structure and features of the present invention, it is summarized that the present invention has the following advantages:
1. Attaching or detaching the heat-dissipating module to or from the housing can be easily achieved by a simple drawing out and inserting operation. As compared with the conventional screw-fastening assembly, the present invention facilitates saving time and efforts in replacing the heat-dissipating module.
2. At the time the heat-dissipating module is assembled to the heat-dissipating module receiving slot, the power connection unit and the power connection port are connected, without needing additional plug-in operation, thereby further simplifying assembling operation of the heat-dissipating modules.
3. Due to the presence of the assistive parts (such as the buckle pieces or the magnetic member), the heat-dissipating module and the heat-dissipating module receiving slot can be combined with enhanced firmness without the risk of loosening.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. A server structure with a replaceable heat-dissipating module, the server structure at least comprising:
a housing, having an interior divided into a main element accommodating space and at least one heat-dissipating module receiving slot, the heat-dissipating module receiving slot at least defined by:
two lateral walls, each having a surface provided with a lengthwise extending sliding groove;
a retaining wall, settled between the two lateral walls for separating the heat-dissipating module receiving slot from the main element accommodating space, the retaining wall further having a plurality of vents for ventilation; and
at least one heat-dissipating module, being replaceably received in the heat-dissipating module receiving slot, the heat-dissipating module serving to dissipate heat generated by electronic devices in the housing for remaining the server structure cool, the heat-dissipating module including:
a heat-dissipating element, enabling the heat-dissipating module to perform heat dissipation; and
two side boards, provided at two sides of the heat-dissipating element, the two side boards being configured to fittingly couple with the sliding grooves on the two lateral walls of the heat-dissipating module receiving slot, so that the heat-dissipating module is replaceably positioned and well supported.

2. The server structure of claim 1, wherein the heat-dissipating element is a fan.

3. The server structure of claim 2, wherein the fan blows wind toward the main element accommodating space so as to introduce cool air outside the housing into the main element accommodating space, thereby remaining the server cool.

4. The server structure of claim 2, wherein the fan blows wind outward from the housing so as to expel warm air in the main element accommodating space from the housing, thereby remaining the server cool.

5. The server structure of claim 1, wherein the heat-dissipating module and the heat-dissipating module receiving slot are fastened together by means of buckle combination.

6. The server structure of claim 1, wherein the heat-dissipating module and the heat-dissipating module receiving slot are fastened together by means of magnetic attraction.

7. A server structure with a replaceable heat-dissipating module, the server structure at least comprising:
a housing, having an interior divided into a main element accommodating space and at least one heat-dissipating module receiving slot, the heat-dissipating module receiving slot at least defended by:
two lateral walls, each having a surface provided with a lengthwise extending sliding groove;
a retaining wall, settled between the two lateral walls for separating the heat-dissipating module receiving slot from the main element accommodating space, the retaining wall further having a plurality of vents for ventilation; and
a power connection port, settled on the retaining wall, having an end facing an interior of the heat-dissipating module receiving slot provided with a plurality of connection terminals;
at least one heat-dissipating module, being replaceably received in the heat-dissipating module receiving slot, the heat-dissipating module serving to dissipate heat generated by electronic devices in the housing for remaining the server structure cool, the heat-dissipating module including:
a heat-dissipating element, enabling the heat-dissipating module to perform heat dissipation;
two side boards, provided at two sides of the heat-dissipating element, the two side boards being configured to fittingly couple with the sliding grooves on the two lateral walls of the heat-dissipating module receiving slot, so that the heat-dissipating module is replaceably positioned and well supported; and
a power connection unit, settled at an end of the heat-dissipating element facing the main element accommodating space, the power connection unit being configured to connect with the plurality of connection terminals on the power connection port for powering the heat-dissipating element.

8. The server structure of claim 7, wherein the heat-dissipating element is a fan.

9. The server structure of claim 8, wherein the fan blows wind toward the main element accommodating space so as to introduce cool air outside the housing into the main element accommodating space, thereby remaining the server cool.

10. The server structure of claim 8, wherein the fan blows wind outward from the housing so as to expel warm air in the main element accommodating space from the housing, thereby remaining the server cool.

11. The server structure of claim 7, wherein a power connection cord is provided at an opposite end of the power connection port facing the main element accommodating space.

12. The server structure of claim 11, wherein a power supply is settled in the main element accommodating space, and the power connection port is connected to the power supply through the power connection cord.

13. The server structure of claim 7, wherein the heat-dissipating module and the heat-dissipating module receiving slot are fastened together by means of buckle combination.

14. The server structure of claim 7, wherein the heat-dissipating module and the heat-dissipating module receiving slot are fastened together by means of magnetic attraction.
